(19) United States
(12) Patent Application Publication
(10) Pub. No.: US 2006/0061393 A1
(43) Pub. Date: Mar. 23, 2006

(54) Method and device for digitally measuring the phase of a signal

(75) Inventors: Maurizio Skerlj, (US); Luca Razzetti, (US); Stefano Gastaldello, (US)

Correspondence Address: SUGHRUE MION, PLLC, 2100 PENNSYLVANIA AVENUE, N.W., SUITE 800, WASHINGTON, DC, 20037, US

(73) Assignee: ALCATEL

(21) Appl. No.: 11/192,357

(22) Filed: Jul. 29, 2005

(30) Foreign Application Priority Data
Sep. 22, 2004 (EP) 04292278.1

(51) Int. Cl. H03D 13/00

(52) U.S. Cl. 327/3

(57) ABSTRACT

A method is disclosed for digitally measuring the phase of a data signal with frequency fx in a transmission network. The method comprises the following steps: providing a counter; increasing the counter upon each occurrence of an event marking the evolution of the data signal with frequency fx and sampling the counter at a first sampling frequency fc, thus obtaining a first sample sequence. According to the method of the invention, the first sample frequency fc is uncorrelated from the frequency fx. The method according to the invention further comprises the steps of sampling the first sample sequence at a second sampling frequency fs, thus obtaining a second sample sequence; and digitally processing said second sample sequence in order to estimate said phase of said data signal. Preferably, said counter is sampled at a frequency fc with fc=α·fx, where α is an irrational number.

### BACKGROUND OF THE INVENTION

1. Field of the Invention

The present invention relates to the field of telecommunication networks and, in particular, to a method and a device for digitally measuring the phase of a signal.

2. Description of the Prior Art

It is known that in a synchronous transmission network, e.g. SDH or Sonet, all the local timing signals are synchronized by a reference timing signal. Said reference timing signal propagates across the entire network and it is employed to synchronize all the nodes of the transmission network.

In other words, a synchronous transmission network implements a “master-slave” synchronization scheme, wherein all the local timing signals (slave) of the single network nodes are recovered by locally regenerating a reference timing signal (master), which propagates across the network through the data flows.

In order to be synchronised, a network element of a synchronous network (e.g. SDH or Sonet) is required to perform functions such as measurement of the reference frequency or regeneration of the reference timing signal. For a proper operation of the network, such functions must be performed by each network element as accurately as possible.

For instance, the ITU-T Recommendation G.813 for SDH standard establishes the requirements of the frequency of the reference timing signal measured by each network element. For instance, the accuracy is fixed to 4.6 ppm for a 2048 kbit/s-operation optimised SDH hierarchy. The ITU-T Recommendation G.813 also defines the requirements of the locally-regenerated timing signals (“Slave Equipment Clock” or SEC), as a function of wander and jitter of the recovered signal phase. For instance, the maximum wander is 40 ns over a 0.1-1 s observation interval, while the maximum jitter is defined by a maximum peak-to-peak amplitude of 0.50 UI over a 60 s interval with a band-pass filter having a 20 Hz-100 KHz passing band, for a 2048 kbit/s-operation optimised-SDH hierarchy.

Devices for phase measurement are known in the art, which can recover the phase of a signal both digitally or analogically. Said devices recover the phase as a function of time Γx(t) of an incoming signal x(t) and, optionally, they estimate its frequency fx by suitably processing the phase. In a synchronous transmission network, said devices for phase measurement can be employed into the network elements:
for recovering the phase and/or frequency of an incoming signal x(t);
for contributing to the regeneration of an incoming signal x(t).

It has to be noticed that timing signals propagate across the network through data flows having bit-rate equal to the frequency of the timing signals. For simplicity, in the following description “signal x(t) with frequency fx” will indicate a data flow with bit-rate fx.

In the first case (phase and/or frequency measurement), a device for phase measurement receives a signal x(t) and outputs, for example, the measurement of its frequency fx. In a network element, said device may for instance provide a measurement of the phase or frequency of the reference timing signal contained in the synchronous data flow; alternatively, said device may provide a measurement of the phase or frequency of an asynchronous data flow coming from asynchronous local networks connected to the synchronous network. In the first case (fx is the reference timing frequency), the measured frequency for example can be stored by the network element which can use it in case of need, for example when the network element eventually looses all the reference timing signals (“holdover operation” in SDH Recommendation ITU-T G.813). In the second case (fx is the frequency of an asynchronous signal), the measured frequency can be used to perform mapping/demapping of asynchronous tributaries into the synchronous numerical structures.

As mentioned above, devices for phase measurement can contribute to the regeneration of an incoming signal x(t). Among regeneration devices, the Phase Locked Loop (or PLL) is one of the most widespread, thanks to the simplicity of its structure and the accuracy of the regenerated signal. A PLL receives a signal x(t) with a frequency fx and, by a proper feedback mechanism, the PLL outputs a local periodic signal xloc(t) having the same frequency fx of the signal x(t). In greater details, a PLL comprises a Phase Detector device and a Voltage Controlled Oscillator (or VCO) in a feedback configuration. The Phase Detector compares the phase of the incoming signal x(t) to the phase of the local signal xloc(t) generated by the VCO and propagating into the loop of the PLL. The phase error signal between the two compared signals is used to modify the operation frequency of the VCO. The PLL is “phase-locked” when the frequency of the local signal xloc(t) is equal to the frequency of the incoming signal x(t).

For instance, in a synchronous network PLLs are placed into the network elements to recover a local timing signal (xloc(t)) from the synchronous data flow (x(t)). The local timing signal can then be used to synchronise the switching functions.

As mentioned above, the devices for phase measurement can be digital or analog. For transmission network application, however, devices for phase measurement are preferably digital, for an easier integration with the other components of the network element, which mainly perform digital signal processing.

A known method for digitally measuring the phase Γx(t) of a signal x(t) provides a counter which evolves at each event marking the evolution of the signal x(t). Afterwards, the counter is sampled at a sampling frequency fs. Ideally, if the frequency fs is equal to an integer sub-multiple of the frequency fx, the sample sequence allows to recover the phase as a function of time Γx(t).

Nevertheless, in real operations the frequency fs is not exactly an integer sub-multiple of the frequency fx. For instance, the incoming signal x(t) may be an asynchronous data flow, whose frequency significantly differs from the synchronous frequencies synchronizing the network element, from which the frequency fs is derived. Alternatively, the incoming signal x(t) may be a synchronous data flow, whose bit-rate is affected by the aforementioned tolerance compliant with the Recommendation ITU-T G.813 (a few parts per million).

In these cases, wherein a detuning occurs between the sampling frequency fs and the signal frequency fx, the measured phase is affected by a periodic error, for reasons which will be explained in details herein after. The period of the phase error increases by decreasing the detuning between fs and fx. For instance, with formulas that will be reported herein after, it is shown that when measuring the phase of an asynchronous signal with a frequency of the synchronous hierarchy (detuning of a few percentage points), the oscillation has a period of a few nanoseconds, corresponding to a spectral distribution of the order of 100 MHz, which is rather easy to filter. On the contrary, when measuring the phase of a synchronous signal through a frequency of the synchronous hierarchy (detuning of a few parts per million), the phase error has a period of a few seconds, corresponding to a spectral distribution in the Hz range, which cannot be filtered by a digital low-pass filter.

### SUMMARY OF THE INVENTION

The general object of the present invention is to provide a method and a device for digitally measuring the phase of a data signal in a transmission network which overcomes the aforesaid problem.

In particular, an object of the present invention is to provide a method and a device for digitally measuring the phase of a data signal in a transmission network in which the phase error due to the detuning between the sampling frequency and the frequency of the signal under measurement has a spectral distribution which is independent from said detuning and which can be easily filtered by low-pass digital filters. Conveniently, such digital filters are similar to those already present into the network elements of a synchronous network.

This and other objects are achieved, according to the present invention, by a method of digital measurement of phase of a data signal in a transmission network according to claim 1, and by a device according to claim 7. Further advantageous features of the present invention are set forth into the respective dependent claims. All the claims are deemed to be an integral part of the present description.

According to the present invention, a method for digitally measuring the phase of a signal is provided, said method including an additional step compared with the known method, wherein the counter is sampled at a first sampling frequency uncorrelated from the frequency of the data signal. Said first sampling frequency can be expressed as fc=α fx, where α is an irrational number. With formulas which will be reported herein after, it is shown that the period and the amplitude of the phase error mainly depends on α; in particular, if α is an irrational number, the phase error is aperiodic.

Therefore, even though the detuning between fs and fx is of only a few parts per million, the phase error can be modified, as it now mainly depends on α. In particular, α can be chosen in order to shift the spectral distribution of the phase error towards a frequency range which can be easily filtered by an electronic low-pass filter.

In a first aspect the present invention provides a method for digitally measuring the phase of a data signal with frequency fx in a transmission network. The method comprises the following steps: providing a counter; increasing the counter upon each occurrence of an event marking the evolution of the data signal with frequency fx and sampling the counter at a first sampling frequency fc, thus obtaining a first sample sequence. According to the method of the invention the first sample frequency fc is uncorrelated from the frequency fx. The method according to the invention further comprises the steps of sampling the first sample sequence at a second sampling frequency fs, thus obtaining a second sample sequence; and digitally processing said second sample sequence in order to estimate said phase of said data signal.

Preferably, said counter is sampled at a frequency fc with fc=α·fx, where α is an irrational number.

Preferably, the step of digitally processing said second sample sequence comprises digitally filtering said second sample sequence.

Optionally, the step of digitally processing said second sample sequence comprises estimating said frequency fx of said data signal.

Advantageously, said frequency fx of said data signal and said second sampling frequency fs are frequencies of a synchronous transmission system.

Preferably, said first sampling frequency fc is generated by a local oscillator independent from said frequency fx and from said second sampling frequency fs.

In a second aspect the present invention provides a device for digitally measuring the phase of a data signal with frequency fx in a transmission network. The device comprises: a counter block, said counter block increasing a counter upon each occurrence of an event marking the evolution of the data signal with frequency fx; and a register, said register sampling the counter at a first sampling frequency fc, thus obtaining a first sample sequence. According to the invention, the first sample frequency fc is uncorrelated from the frequency fx. In addition, the device further comprises: a sampler for sampling the first sample sequence at a second sampling frequency fs, thus obtaining a second sample sequence; and a processor for digitally processing the second sample sequence in order to estimate the phase of the data signal.

Preferably, the register is a register sampling the counter at a first sampling frequency fc with fc=α·fx, where α is an irrational number.

Preferably, the processor digitally processes the second sample sequence by digitally filtering the second sample sequence.

Optionally, the processor digitally processes the second sample sequence by estimating said frequency fx of said data signal.

Advantageously, said device is a part of a Phase Locked Loop.

Advantageously, said device is comprised in a network element.

Further features and advantages of the present invention will become clear from by the following detailed description, given by way of example and not of limitation, to be read with reference to the accompanying drawings.

### BRIEF DESCRIPTION OF THE DRAWINGS

In the drawings:

FIG. 1 shows a graph of a periodic signal x(t) with frequency fx;

FIG. 2 shows a graph of the normalised phase Γx(t)/2π of the signal x(t) and of the counter c(t) according to the known method;

FIG. 3 shows a graph of the normalised phase Γx(t)/2π of the signal x(t), of the counter c(t) and of the sample sequence {sₙ} according to the known method, in an ideal case in which fs is an integer sub-multiple of fx;

FIGS. 4a and 4b show graphs of the normalised phase Γx(t)/2π of the signal x(t), of the counter c(t) and of the sample sequence {sₙ} according to the known method, in a real case in which fs is respectively higher (FIG. 4a) and lower (FIG. 4b) than an integer sub-multiple of fx;

FIG. 5 shows a graph of the normalised phase Γx(t)/2π, of the counter c(t) and of the sample sequence {sₙ} and a graph of the phase error ε(t) and of the phase error sequence {εₙ} according to the known method, in an ideal case in which fs is an integer sub-multiple of fx;

FIG. 6a e 6b show a graph the normalised phase Γx(t)/2π, of the counter c(t) and of the sample sequence {sₙ} and a graph of the phase error ε(t) and of the phase error sequence {εₙ} according to the known method, in real cases wherein fs is respectively higher (FIG. 6a) and lower (FIG. 6b) than an integer sub-multiple of fx;

FIG. 7 shows a graph of the phase error ε(t), of the phase error sequence {εₙ′} in the ideal case (fs equal to an integer sub-multiple of fx), of the phase error-sequence {εₙ″} in a real case (detuning between fs and fx) according to the known method, and of the phase error sequence {εₙ′″} in a real case (detuning between fs and fx) according to the invention;

FIG. 8 shows the scheme of a known device for digital measurement of the phase of a signal;

FIG. 9 shows the scheme of a device for digital measurement of the phase of a signal according to the present invention; and

FIG. 10 shows a PLL comprising a device for digital measurement of the phase of a signal according to the present invention.

### BEST MODE FOR CARRYING OUT THE INVENTION

In all the graphs representing a variable as a function of time (x(t), c(t), etc . . . ), the time scale is represented in arbitrary units.

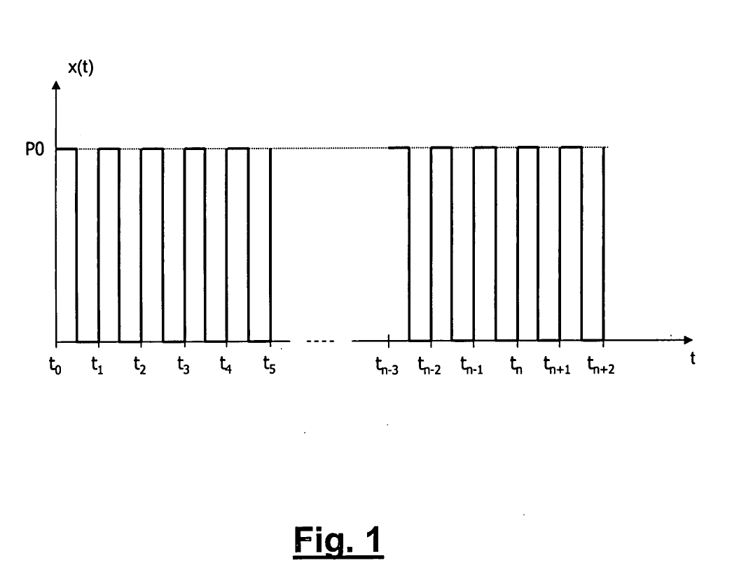

FIG. 1 shows a graph of a periodic signal x(t) with amplitude P0 and frequency fx. The signal x(t) exhibits a rising edge at each instant t₁, t₂, . . . tₙ, where t₁=1/fx, t₂=2/fx, . . . tₙ=n/fx. In other words, each period of the periodic signal x(t) starts with a rising edge.

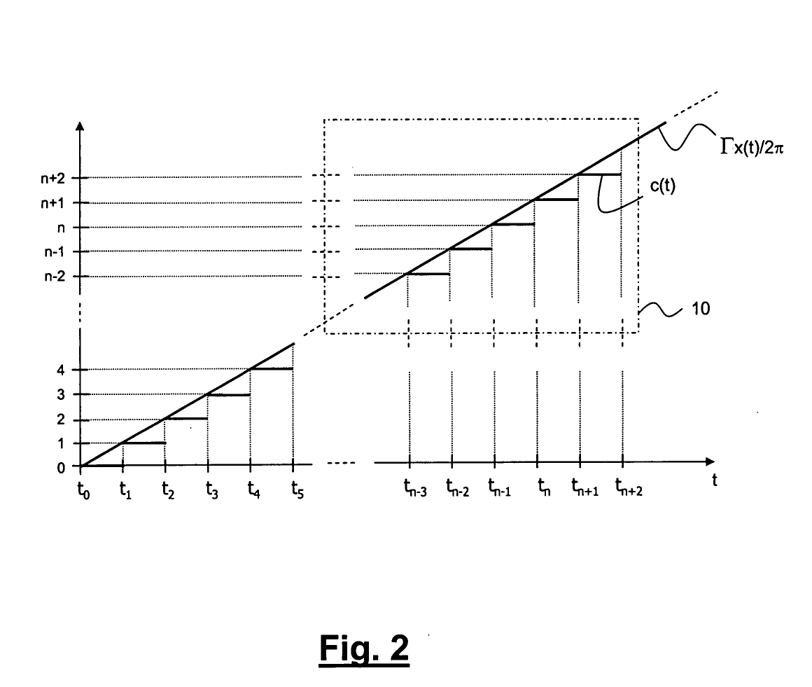

It is known that the phase Γx(t) of the periodic signal x(t) evolves in time according to the relation Γx(t)=2π·fx·t, i.e. Γx(t) is equal to an integer multiple of 2π in the time instants t₁, t₂, . . . tₙ. Thus, in the time instants t₁, t₂, . . . tₙ, wherein raising edges of the periodic signal x(t) occur, the normalised phase Γx(t)/2π of the signal x(t) is equal to an integer value, as shown in FIG. 2. In particular, Γx(t₁)/2π=1, Γx(t₂)/2π=2, . . . Γx(tₙ)/2πt=n.

As mentioned above, in a known method for digitally measuring the phase of a signal, a counter is firstly provided. The counter value is increased upon each occurrence of an event marking the evolution of the data signal. FIG. 2 shows for example a counter c(t) which is increased at each rising edge of the periodic signal x(t). Hence:
c(t)=0 where t₀<t<t₁;
c(t)=1 where t₁<t<t₂;
c(t)=2 where t₂<t<t₃; and, in general,
c(t)=n where tₙ<t<tₙ₊₁.

Comparing the normalised phase Γx(t)/2π with the counter c(t), it can be noticed that in each period the value of the counter c(t) is the integer part of the normalised phase Γx(t)/2π. Thus, the counter c(t) is equal to the normalised phase Γx(t)/2π with a phase error ε(t). The phase error ε(t) is the fractional part of the normalised phase Γx(t)/2π and it is defined as ε(t)=Γx(t)/2π−c(t).

It has to be noticed that, in the present description, x(t) is a periodic signal. Nevertheless, as mentioned above, the method of measurement according to the present invention can be applied to data signals, i.e. to signals which comprise a sequence of bit with bit-rate fx. To perform a digital measurement of the phase of this kind of signals, each bit “1” or “0” must be encoded so that in each period there occurs an event for incrementing the counter c(t). It is the case, for example, of bipolar encodings, wherein the bit “1” is encoded as a “high-low” transition and the bit “0” is encoded as a “low-high” transition. Therefore, independently of the bit sequence, each period includes a transition; the counter c(t) is then increased each time a transition occurs.

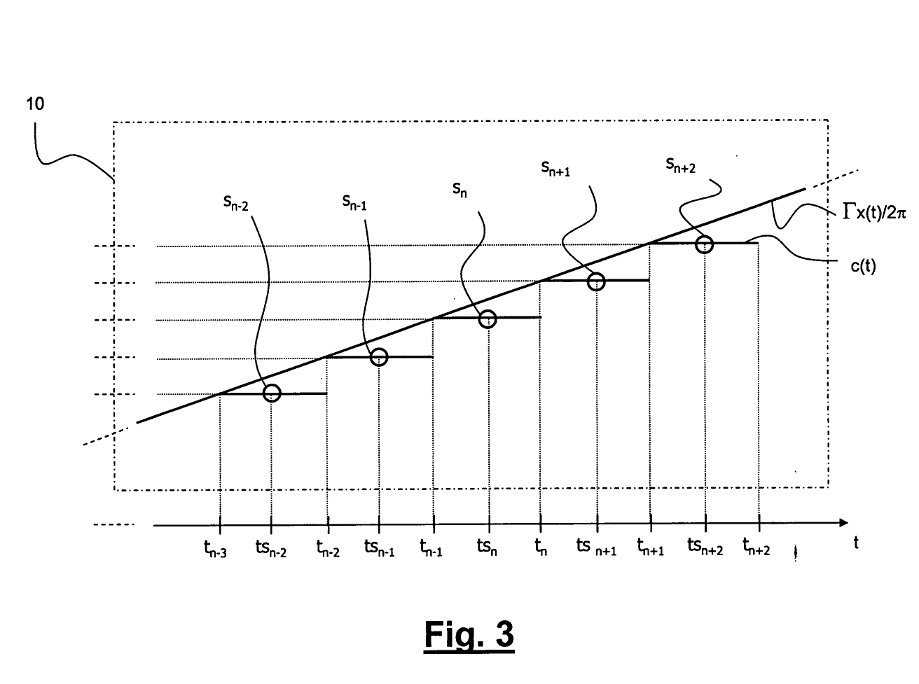

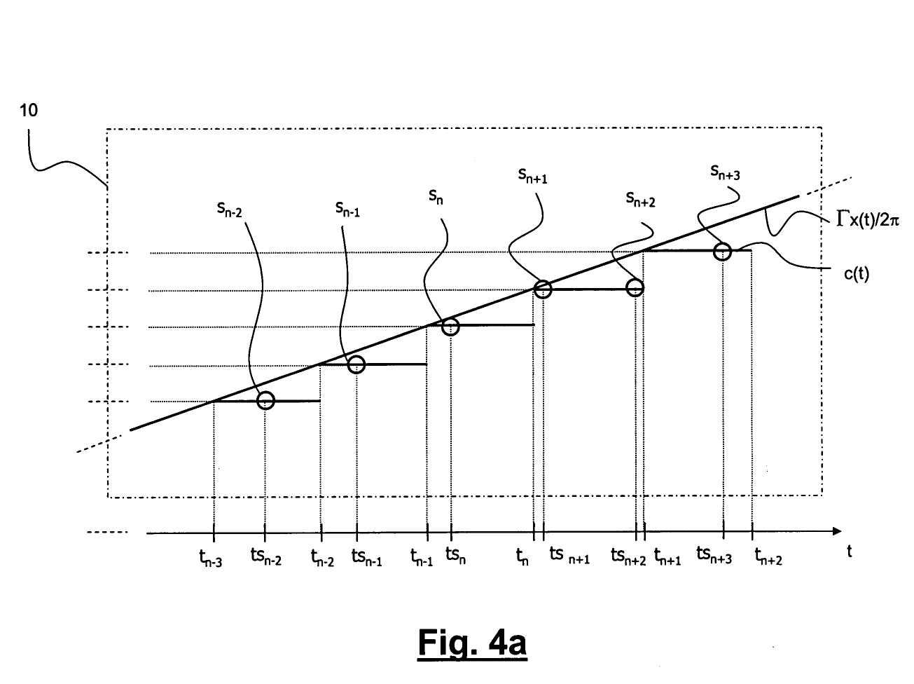

The next step of the known method for measuring the phase of the signal x(t) comprises sampling the counter c(t) at a sampling frequency fs, i.e sampling the counter c(t) at a sequence of time instants {tsₙ} of sampling instants ts₁, ts₂, . . . tsₙ. Two consecutive sampling instants tsₙ e tsₙ₊₁ are spaced by a sampling period Ts=1/fs. A sample sequence {Sₙ}=s₁, s₂, . . . sₙ is thus obtained. In particular, referring to FIG. 3:
at tsₙ₋₂:sₙ₋₂=c(tsₙ₋₂);
at tsₙ₋₁:sₙ₋₁=c(tsₙ₋₁);
at tsₙ:sₙ=c(tsₙ);
at tsₙ₊₁:sₙ₊₁=c(tsₙ₊₁); and
at tsₙ₊₂:sₙ₊₂=c(tsₙ₊₂).

As already mentioned, the counter c(t) is the normalised phase Γx(t)/2π affected by an error ε(t). However, if the sampling frequency fs is such that the sampling instants always occur in the same position relatively to the signal periods, the phase error affecting each sample of the sequence {sₙ} is the same for all the samples. In other words, if the sampling frequency fs is equal to fx or to an integer sub-multiple of the frequency fx, the sequence {sₙ} allows to recover the normalised phase Γx(t)/2π, shifted by a phase offset.

In the following, for clarity reasons, only the case with sampling frequency fs equal to the frequency fx will be treated. Nevertheless, all the considerations may be applied to the more general case with fs integer sub-multiple of fx.

FIG. 3 shows an ideal case, in which fs is exactly equal to fx. It can be noticed that all the sampling instants are placed in the middle of each period; therefore, the sample sequence {sₙ} is a ramp, which is analogous to the normalised phase Γx(t)/2π ramp, shifted by a constant phase offset.

However, in real cases fs is not exactly equal to fx (or to an integer sub-multiple of fx). For instance, in synchronous networks, the frequency fs is derived from the reference timing signal, thus being a sub-multiple of one of the synchronous hierarchy frequencies. The signal x(t) may be either a synchronous signal, or an asynchronous signal. As mentioned before, in the first case the detuning between fs and fx may be of a few parts per million; in the second case, the detuning between fs and fx may be of a few percentage points.

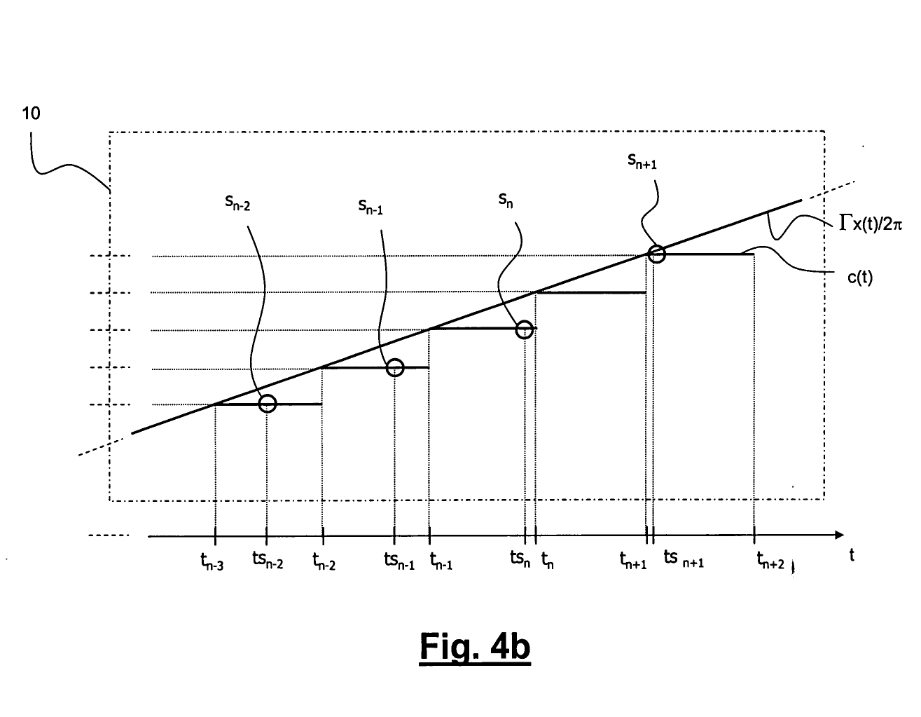

FIGS. 4a and 4b show the effect of sampling in two real cases, wherein the sampling frequency fs and the frequency fx are detuned. In particular, FIG. 4a refers to the case wherein fs is higher than fx. It is assumed that in a certain signal period, for example the period comprised between tₙ₋₃ e tₙ₋₂, the sampling instant tsₙ₋₂ is placed in the middle of the period. As fs is higher than fx, in the following signal periods the sampling instants will tend to move towards the beginning of the period. Therefore, each sample of the sequence {sₙ} is affected by a phase error, with respect to the normalised phase Γx(t)/2π, that changes for each sample. Besides, as the sampling period 1/fs is lower than the signal period, after a certain number of sampling instants there will be a signal period (between tₙ e tₙ₊₁ in FIG. 4a) comprising two sampling instants (tsₙ₊₁ e tsₙ₊₂). The resulting sample sequence {sₙ} thus exhibits an anomaly with respect to the linear trend of the normalised phase ramp.

Similarly, FIG. 4b shows the case wherein fs is lower than fx. Also in this case, in a certain signal period, for instance the one included between tₙ₋₃ e tₙ₋₂, the sampling instant is placed exactly in the middle of the signal period. As fs is lower than fx, the following sampling instants tend to move toward the end of the signal period. Hence, each sample of the sequence {sₙ} is affected by a different phase error. Besides, as the sampling period 1/fs is higher than the signal period, after a certain number of sampling instants there will be a signal period (between tₙ e tₙ₊₁ in FIG. 4b) comprising no sampling instants. The resulting sample sequence {sₙ} thus exhibits an anomaly with respect to the linear trend of the normalised phase ramp.

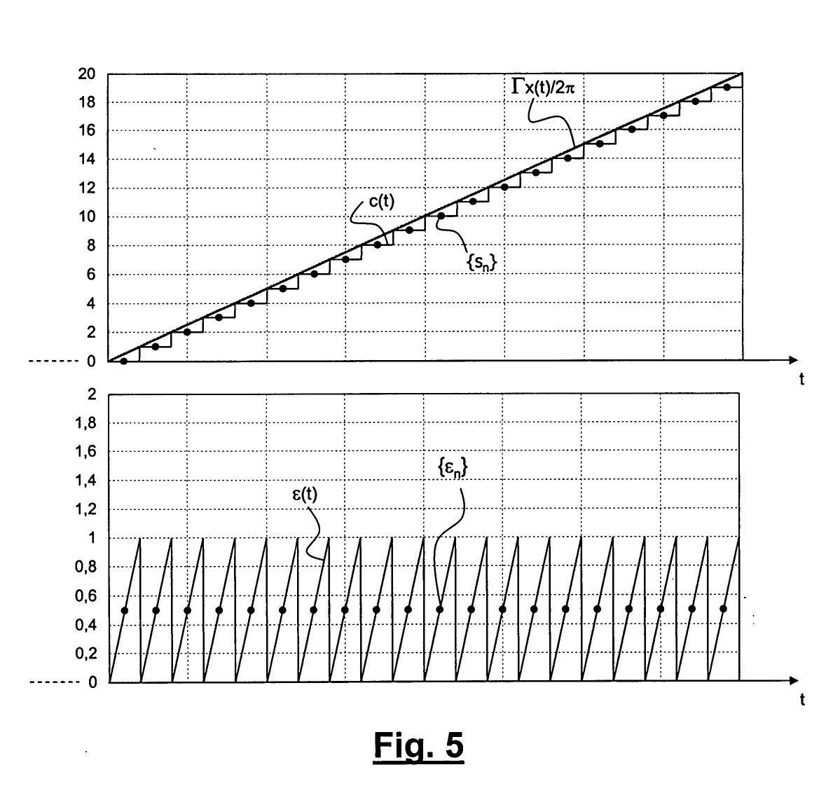

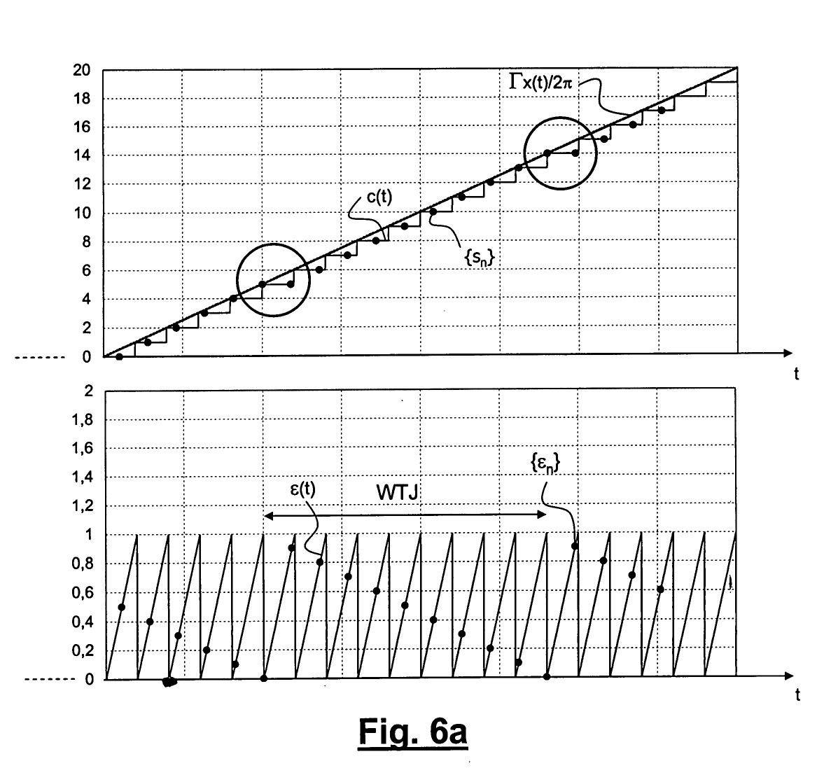

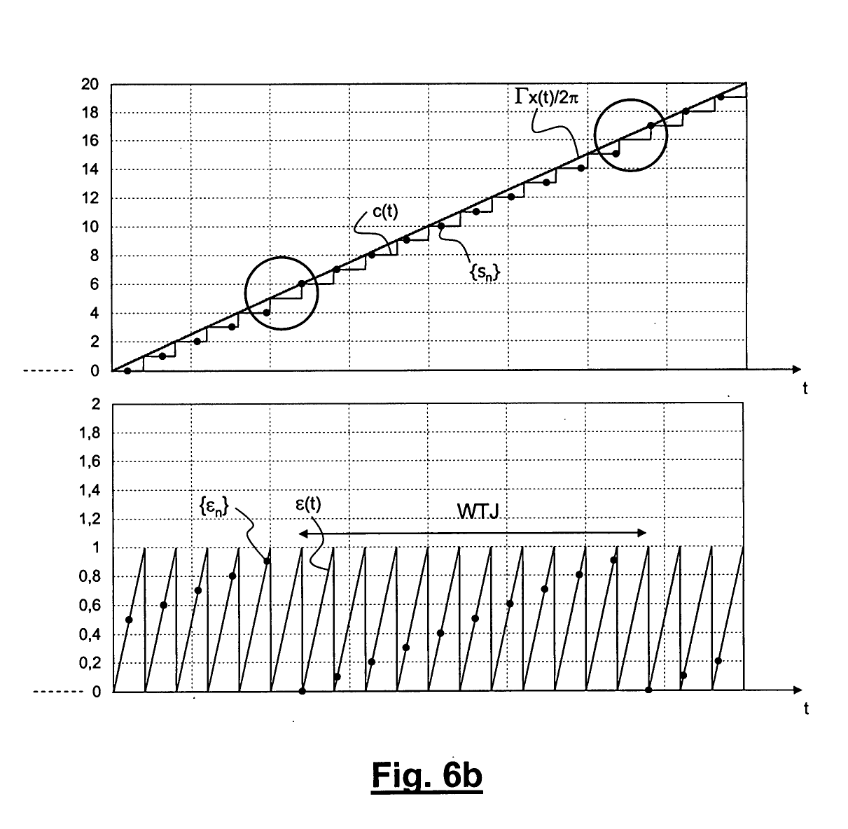

FIGS. 5, 6a and 6b show the effect of the detuning between fs and fx over the phase error occurring when considering at each sampling instant tsₙ the sample sₙ instead of the actual value of normalised phase Γx(tsₙ)/2π, according to the known method. In particular, FIG. 5 is referred to the ideal case wherein fs is equal to fx. FIGS. 6a and 6b are referred to two real cases wherein fs is respectively higher and lower than fx.

In FIG. 5, it can be noticed, as mentioned by reference to FIG. 3, that the sample sequence {sₙ} has a linear trend, thus corresponding, except a phase offset, to the signal normalised phase. In other words, as shown in the lower graph of FIG. 5, in this case the sequence of phase errors {εₙ} affecting the sequence {sₙ}, wherein each εₙ is defined as εₙ=Γx(tsₙ)/2π−sₙ, is constant.

FIG. 6a shows a real case in which fs is higher than fx. In this case, the sample sequence {sₙ} exhibits anomalies, as described by reference to FIG. 4a. Such anomalies (highlighted by circles in FIG. 6a) are periodic with a period WTJ. In other words, as shown in the lower graph of FIG. 6a, in this case the sequence of phase errors {εₙ} has a saw-tooth shape with period WTJ. Filtering such a phase error thus requires filtering a 1/WTJ frequency component.

FIG. 6b shows a second real case in which fs is lower than fx. In this case, the sample sequence {sₙ} exhibits anomalies, as described by reference to FIG. 4b. Such anomalies (highlighted by circles in FIG. 6b) are periodic with a period WTJ. In other words, as shown in the lower graph of FIG. 6b, in this case the sequence of phase errors {εₙ} has a saw-tooth shape with period WTJ. Filtering such a phase error thus requires filtering a 1/WTJ frequency component.

It is possible to estimate the period WTJ of the sequence of phase errors through the formulas reported herein after.

Under the assumption that fs can be expressed as fs=(1+s)·fx, in each period of the signal x(t), each sampling instant tsₙ moves, relatively to the corresponding signal period, of a time interval
ΔT=s/fx.

The number of signal periods required by the time instant to move across the entire signal period is
N=(1/fx)/ΔT.

Hence, an anomaly will occur when the sampling instant has passed through the whole period of the signal x(t), i.e.
WTJ=(1/fx)·N=1/(fx·s).

For instance, it is assumed that fs equal to 77 MHz. If the signal x(t) is a synchronous signal, s is equal to a few parts per million, according to the ITU-T Recommendation G.813. Thus,
WTJ(synch)=1/(77 MHz·10⁻⁶)=12 ms.

Digitally filtering such an anomaly requires filtering a spectral distribution placed at 1/WTJ(synch)=77 Hz. It is clear that such a filtering cannot be performed by a low-pass digital filter, as the frequency is too low.

On the other hand, it is not possible to modify the sampling frequency fs, as it is derived by the synchronous hierarchy frequencies by means of dividers, which provides integer sub-multiples of fs. Using a sub-multiple of fs, however, does not eliminate anomalies of the sequence {sₙ} and the consequent periodicity of the sequence of phase errors {εₙ}.

According to the present invention, a method for digitally measuring the phase of a signal is provided, wherein the spectral distribution of the phase error can be modified. Hence, the method according to the invention comprise an additional step with respect to the known method, wherein the counter c(t) is sampled at a first sampling frequency fc uncorrelated from the signal frequency fx, thus obtaining a first sample sequence {cₙ}. Said first sample sequence {cₙ} is in turn sampled at a second sampling frequency fs, thus obtaining a second sample sequence {sₙ}, which is finally digitally processed.

With the method according to the invention, even though the detuning between fs and fx is very low, as in synchronous transmission system applications, the second sequence {sₙ} exhibits anomalies with respect to the ramp of the normalised phase with a period WTJ mainly dependent on the ratio between the first sampling frequency fc and the signal frequency fx. In particular, if fc=α fx, with α irrational number, by suitably tailoring α it is possible to modify the sequence of phase errors {εₙ}.

Actually, if α is an irrational number (i.e. fs and fx are uncorrelated), the sequence of phase errors {εₙ} becomes aperiodic. As mentioned referring to FIGS. 6a and 6b, if the ratio between fs and fx is a fractional value the anomalies of the sample sequence are periodic. On the contrary, as α is an irrational number, anomalies of the sample sequence {cₙ} are not exactly periodic, as each sample cₙ which immediately follows an anomaly falls in a different position relatively to the signal period. Hence, anomalies are not exactly periodic in time, so the amplitude of the spectral distribution of the sequence of phase errors {εₙ} is reduced.

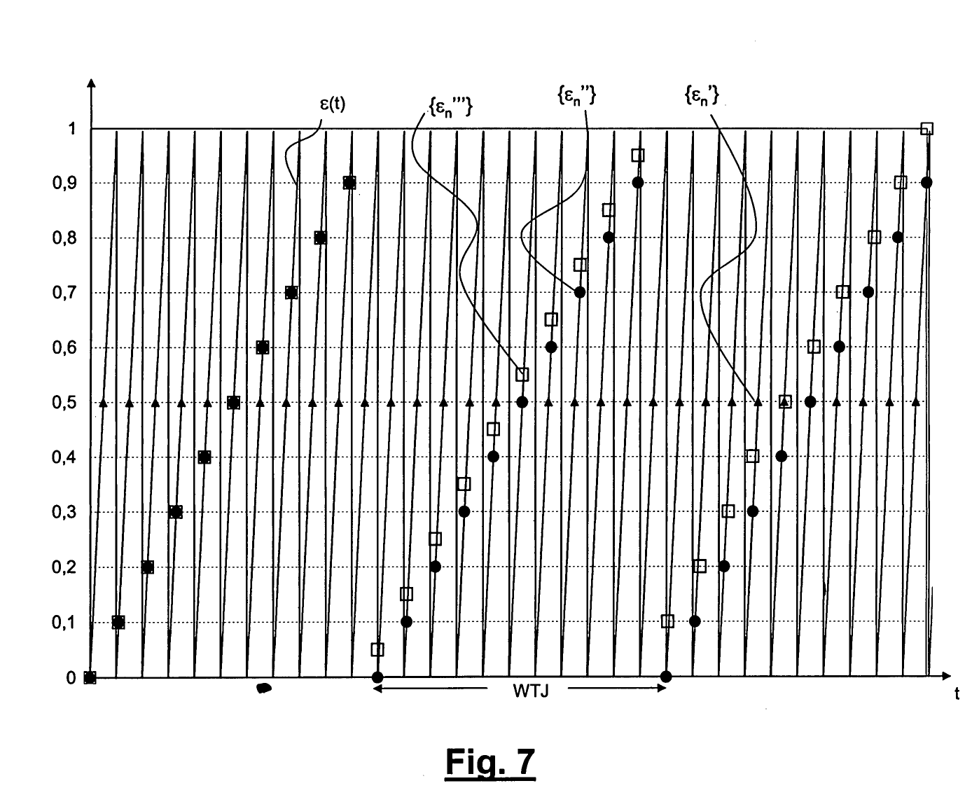

For a deeper understanding of the invention, reference can be made to the above mentioned phase error ε(t). Reference will be now made to FIG. 7, wherein a graph of the error as a function of time ε(t) is reported. The error ε(t), defined as ε(t)=Γx(t)/2π−c(t), has a periodic saw-tooth shape. The sequence {εₙ′}, represented by triangles in FIG. 7, is the sequence of phase errors affecting the sequence {sₙ} in the ideal case, wherein fs is equal to fx. As already mentioned, each phase error εₙ′ affecting each sample sₙ is constant, the sequence {sₙ} thus corresponding to the normalised phase shifted by an offset. The sequence {εₙ″}, represented in FIG. 7 by circles, is the sequence of phase errors affecting the sequence {sₙ} in a real case, wherein fs and fx are detuned. In this case, the phase error εₙ″ affecting each sample sₙ is not constant, and the sequence {εₙ″} has period WTJ.

The sequence {εₙ′″}, represented in FIG. 7 by squares, is the sequence of phase errors affecting the sequence {sₙ} in an embodiment of the method according to the present invention. As already mentioned, the sequence {εₙ′″} is not periodic, since the sampling time instants always fall in different positions of the signal period. In the following, the formulas describing {εₙ′″} will be derived.

For simplicity, it will be assumed that α is an irrational number close to a fractional number q/p. Therefore Tc=p/q·Tx, while Ts=(1+d) Tx. Sampling the phase error ε(t) with a first sampling period Tc and then with a second sampling period Ts, the sequence {εₙ′″} can be expressed as:

$$\{ {ɛ}_{n}^{′′′} \} = \frac{nTs}{Tx} - ⌊ \frac{Tc}{Tx} ⌊ \frac{nTs}{Tc} ⌋ ⌋ = n ( 1 + d ) - ⌊ ⌊ \frac{qn ( 1 + d )}{p} ⌋ \frac{p}{q} ⌋$$

where
n=└t·fs┘

and where └·┘ is the integer operator. The ratio p/q can be expressed as p/q=(m+1)/m; the previous formula thus can be rewritten as:

$$\{ {ɛ}_{n}^{′′′} \} = nd - ⌊ ⌊ \frac{mn}{m + 1} + \frac{ndm}{m + 1} ⌋ \frac{m + 1}{m} - n ⌋ .$$

As d is in general very low, the term nd can be considered as a constant K. Therefore, the sequence of phase errors can be expressed as:

$$\{ {ɛ}_{n}^{′′′} \} = K - ⌊ ⌊ \frac{mn}{m + 1} + \frac{Km}{m + 1} ⌋ \frac{m + 1}{m} - n ⌋ .$$

It is now possible to demonstrate that the sequence of phase errors, when filtered, is substantially independent from K, i.e. from d; in other words, the sequence of phase errors is independent from the detuning between fs and fx. By digitally filtering the sequence {εₙ′″}, the filtered sequence {εₙ′″}^{filt} can be written as:

$${\{ {ɛ}_{i}^{′′′} \}}^{filt} = \frac{1}{m + 1} {\sum }_{n = 1}^{m + 1} {ɛ}_{n + i ( m + 1 )} = K - \frac{1}{m + 1} {\sum }_{n = 1}^{m + 1} ⌊ ⌊ \frac{nm}{m + 1} + \frac{Km}{m + 1} ⌋ \frac{m + 1}{m} - n ⌋ .$$

As the term of the summation is a periodic function with period m+1, it is possible to eliminate the dependence on i. Rewriting K as K=k+γ, where k is the integral part of k and γ is the fractional part of K, the filtered sequence can be further expressed as:

$${\{ {ɛ}_{i}^{′′′} \}}^{filt} = γ - \frac{1}{m + 1} {\sum }_{n = 1}^{m + 1} ⌊ ⌊ \frac{nm}{m + 1} + \frac{γ m}{m + 1} ⌋ - n + ⌊ \frac{nm}{m + 1} + \frac{γ m}{m + 1} ⌋ \frac{1}{m} ⌋ .$$

It can be noticed that the first two terms of the summation are always integer numbers, while the third term provides a fractional number. The third term is an integer number only when multiplied by a number higher than m, i.e. the two following conditions must be satisfied:
nm+γm≧m(m+1); and
n≧m+(1−γ).

Both these conditions are satisfied only when n=m+1, and, in this case, the third term is equal to 1. The filtered sequence can then be rewritten as:

$${\{ {ɛ}_{i}^{′′′} \}}^{filt} = γ - \frac{1}{m + 1} \{ 1 + {\sum }_{n = 1}^{m + 1} ⌊ n + \frac{γ m - n}{m + 1} ⌋ - {\sum }_{n = 1}^{m + 1} n \} .$$

It can be noticed that:

$$\begin{matrix}⌊ n + \frac{γ m - n}{m + 1} ⌋ = n when n \leq γ m , while \\ ⌊ n + \frac{γ m - n}{m + 1} ⌋ = n - 1 when n > γ m . \end{matrix}$$

The final expression of the filtered sequence of phase errors is then:

$${\{ {ɛ}_{i}^{′′′} \}}^{filt} = \frac{m}{m + 1} + ( γ - \frac{⌊ γ m ⌋}{m + 1} )$$

It can be noticed that the filtered sequence {εₙ′″}^{filt} depends on m, which is related to the ratio between the first sampling frequency fc and the signal frequency fx. The weak dependence of the sequence on d is expressed by the term γ. It can also be noticed that while in the known method the phase error varies in a 0-1 range, in the method according to the present invention the maximum value of the phase error is about 2/m.

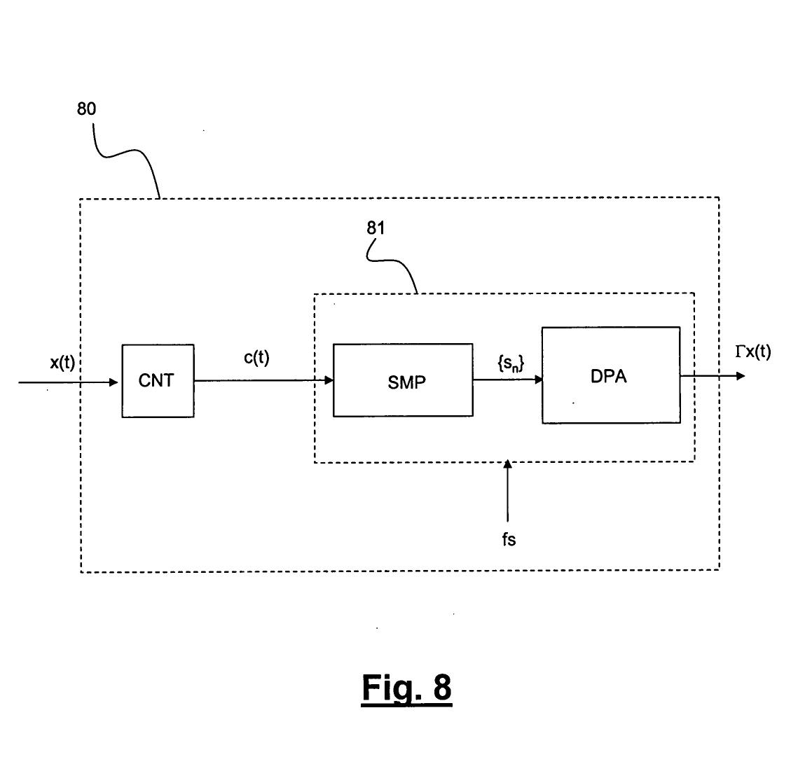

FIG. 8 shows a known device for digitally measuring the phase of a signal. The device 80 comprises a counter block CNT, with an input port for receiving a signal, and an output port connected to the input port of a digital device 81, in turn comprising a sampler SMP connected to a processor DPA, which implements a digital processing algorithm. A signal x(t) at the input of the device 80 is received from the counter CNT, which outputs a counter c(t). Said counter c(t) is sent to the digital device 81, which is synchronised by a timing signal with frequency fs. In the digital device 81, the counter c(t) is firstly sampled by the sampler SMP with the sampling frequency fs, thus obtaining a sample sequence {sₙ}. The sampler then sends the sample sequence {sₙ} to the processor DPA, which digitally processes the sequence and possibly estimates the frequency of the input signal x(t).

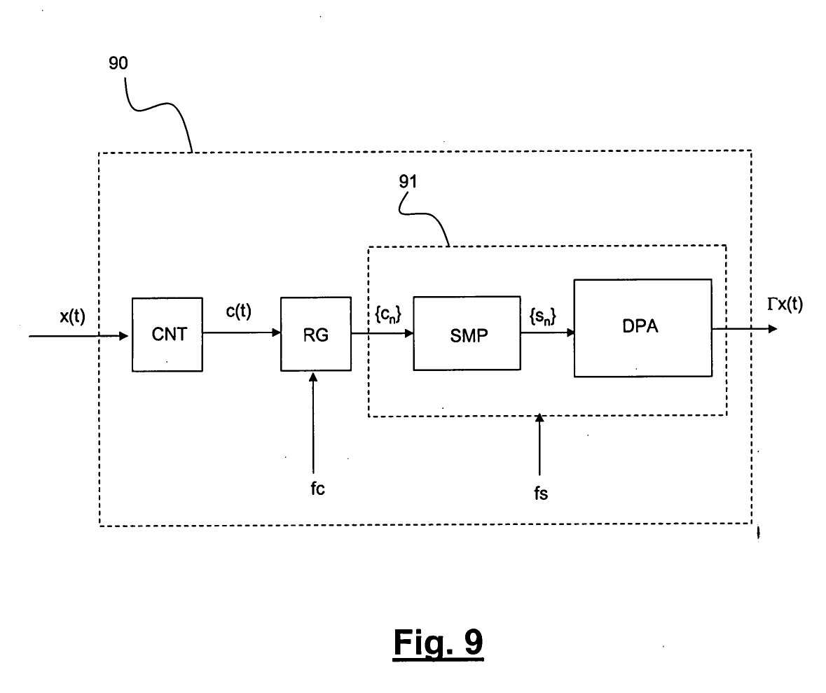

FIG. 9 shows a device for digitally measuring the phase of a signal according to the present invention. Said device is advantageously employed into a network element of a synchronous transmission network. The device 90 comprises a counter block CNT, with an input port for receiving a signal and an output port connected to an input port of a register RG. The register RG has an output port which is connected to an input of a digital device 91, in turn comprising a sampler SMP connected to a processor DPA, which implements a digital processing algorithm. A signal x(t) at the input of the device 90 is received by the counter block CNT, which extrapolates a counter c(t) from the signal x(t). Said counter c(t) is sent to the register RG, which samples it at a first sampling frequency fc, thus obtaining a first sample sequence {cₙ}. Said first sample sequence {cₙ} is sent to the digital device 91, which is synchronised by a timing signal with frequency fs. In the digital device 91, the sequence {cₙ} is firstly sampled by the sampler SMP with the sampling frequency fs, thus obtaining a sample sequence {sₙ}. The sampler then sends the sample sequence {sₙ} to the processor DPA, which digitally processes the sequence and possibly estimates the frequency of the input signal x(t).

Such a device can be employed, for example, in network nodes of a synchronous network, as mentioned before. In this application, the frequency fs is obtained by a frequency of the synchronous hierarchy by suitable dividers, fs thus being an integer sub-multiple of a frequency of the synchronous hierarchy. On the contrary, fc is generated by a local oscillator uncorrelated from the timing signal available in the network element. This guarantees the uncorrelation between fc and fx.

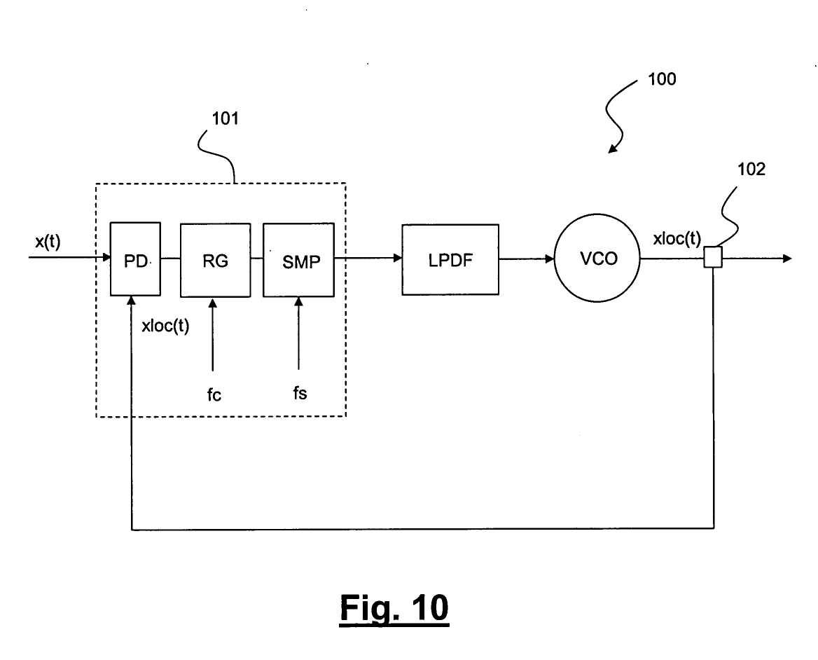

As mentioned in the introduction, the device for digitally measuring the phase according to the invention can be employed into a device for the regeneration of a periodic signal x(t), and, more in particular, into devices such as the so-called “Phase Locked Loop” (PLL). FIG. 10 shows a PLL 100 wherein the phase recovery is performed according to the method of the present invention. The PLL 100 comprises a phase device for phase digital measurement 101, a low-pass digital filter LPDF and a voltage-controlled local oscillator VCO. At the output of the VCO, a junction 102 with two branches is provided, wherein a first branch is the output port of the PLL, while the second branch is connected to the device for phase digital measurement 101. The device for phase digital measurement 101 in turn comprises a phase detector PD, a register RG operating at a first sampling frequency fc and a sampler SMP working at a second sampling frequency fs.

A signal x(t) with frequency fx at the input of the PLL s compared by the phase detector PD with the local signal xloc(t) coming from the VCO through the second branch of the junction 102. The PD outputs a signal proportional to the phase difference between x(t) and xloc(t). The phase difference is firstly sampled by the register RG at the frequency fc, and then by the sampler SMP at the frequency fs. According to the present invention, the frequency fc is selected so that the sample sequence corresponding to the phase difference exhibits anomalies which can be easily filtered by the filter LPDF. The sample sequence corresponding to the phase difference is then digitally filtered by the filter LPDF. The filtered sequence is finally sent to the VCO. If this filtered sequence is different from a null sequence, the VCO modifies its operation frequency; if the filtered sequence is a null sequence, the phases of x(t) and xloc(t) are equal, and the VCO does not modify its operating frequency.

1. A method for digitally measuring a phase (Γx(t)) of a data signal (x(t)) with frequency fx in a transmission network, said method comprising:
providing a counter (c(t));
increasing said counter (c(t)) upon each occurrence of an event marking the evolution of the data signal (x(t)) with frequency fx;
sampling the counter (c(t)) at a first sampling frequency fc, thus obtaining a first sample sequence ({cₙ}),
wherein said first sample frequency fc is uncorrelated from said frequency fx, and wherein the method further comprises:
sampling said first sample sequence ({cₙ}) at a second sampling frequency fs, thus obtaining a second sample sequence ({sₙ}); and
digitally processing said second sample sequence ({sₙ}) in order to estimate said phase (Γx(t)) of said data signal (x(t)).

2. The method according to claim 1, wherein the step of sampling said counter (c(t)) at said first sampling frequency fc uncorrelated from said frequency fx comprises sampling said counter (c(t)) at said frequency fc with fc=α·fx, where α is an irrational number.

3. The method according to claim 1, wherein the step of digitally processing said second sample sequence ({sₙ}) comprises digitally filtering said second sample sequence ({sₙ}).

4. The method according to claim 1, wherein the step of digitally processing said second sample sequence ({sₙ}) comprises estimating said frequency fx of said data signal (x(t)).

5. The method according to claim 1, wherein said frequency fx of said data signal (x(t)) and said second sampling frequency fs are frequencies of a synchronous transmission system.

6. The method according to claim 1, wherein said first sampling frequency fc is generated by a local oscillator independent from said frequency fx and from said second sampling frequency fs.

7. A device for digitally measuring a phase (Γx(t)) of a data signal (x(t)) with frequency fx in a transmission network, said device comprising:
a counter block (CNT), said counter block (CNT) increasing a counter (c(t)) upon each occurrence of an event marking the evolution of the data signal (x(t)) with frequency fx; and
a register (RG), said register (RG) sampling the counter (c(t)) at a first sampling frequency fc, thus obtaining a first sample sequence ({cₙ}),
wherein said first sample frequency fc is uncorrelated from said frequency fx, and wherein said device further comprises:
a sampler (SMP), said sampler (SMP) sampling said first sample sequence ({cₙ}) at a second sampling frequency fs, thus obtaining a second sample sequence ({sₙ}); and
a processor (DPA), said processor (DPA) digitally processing said second sample sequence ({sₙ}) in order to estimate said phase (Γx(t)) of said data signal (x(t)).

8. The device according to claim 7, wherein said register (RG) is a register sampling the counter (c(t)) at a first sampling frequency fc with fc=α·fx, where α is an irrational number.

9. The device according to claim 7, wherein said processor (DPA) digitally processes said second sample sequence ({sₙ}) by digitally filtering said second sample sequence ({sₙ})

10. The device according to claim 7, wherein said processor (DPA) digitally processes said second sample sequence ({sₙ}) estimating said frequency fx of said data signal (x(t)).

11. The device according claim 7, wherein said frequency fx of the data signal (x(t)) and said second sampling frequency fs are frequencies of a synchronous transmission system.

12. The device according to claim 7, wherein said first sampling frequency fc is generated by a local oscillator independent from said frequency fx and from said second sampling frequency fs.

13. The device according to claim 7, wherein said device is a part of a Phase Locked Loop (100).

14. A network element comprising a device according to claim 7.
